(19) United States
(12) Patent Application Publication
(10) Pub. No.: US 2009/0224412 A1
(43) Pub. Date: Sep. 10, 2009

(54) NON-PLANAR SUBSTRATE STRIP AND SEMICONDUCTOR PACKAGING METHOD UTILIZING THE SUBSTRATE STRIP

(75) Inventor: Wen-Jeng FAN, Hukou Shiang (TW)

Correspondence Address: Muncy, Geissler, Olds & Lowe, PLLC, P.O. BOX 1364, FAIRFAX, VA, 22038-1364, US

(73) Assignee: POWERTECH TECHNOLOGY CORPORATION

(21) Appl. No.: 12/042,122

(22) Filed: Mar. 4, 2008

(51) Int. Cl. H01L 23/13; H01L 21/58

(52) U.S. Cl. 257/782; 438/108; 257/E21.505; 257/E23.004

(57) ABSTRACT

A non-planar substrate strip for semiconductor packages is revealed, primarily comprising a substrate core having an external surface, an external solder mask and a patterned thick solder mask. The external solder mask covers the external surfaces of a plurality of substrate units of the non-planar substrate strip. The patterned thick solder mask is formed on the opposing surface of the substrate core only to cover a frame of the substrate core to expose the die-attaching surface of the substrate units. The patterned thick solder mask is thicker than the external solder mask. Therefore, the substrate strengths and die-attaching strengths of the substrate strip are enhanced. The substrate warpage is restrained during manufacturing the substrate strip. A semiconductor packaging method utilizing the substrate strip is also revealed.

### FIELD OF THE INVENTION

The present invention relates to a chip carrier for semiconductor packages, especially to a non-planar substrate strip and semiconductor packaging method utilizing the substrate strip.

### BACKGROUND OF THE INVENTION

In the conventional semiconductor package, substrate strips are implemented as chip carriers, including a plurality of substrate units arranged in an array. After semiconductor packaging processes, the substrate strip is singulated to be a plurality of semiconductor packages to achieve mass production with lower costs. However, substrate warpage will cause misalignment of the substrate strip during handling and processing leading to poor packaging yields. The conventional substrate strip is planar where solder masks are disposed on the die-attaching surface and on the external surface of the substrate strip, therefore, substrate warpage is not an issue. In one of conventional substrates, the solder mask on the die-attaching surface is eliminated with the die-attaching material directly attached to the core of the substrate strip leading to unbalanced stresses exerted on the die-attaching surface and on the external surface of the substrate. If a substrate strip with a plurality of substrate units is implemented as chip carriers, substrate warpage will become worse. Accordingly, the substrate having single layer of solder mask is singulated from a substrate strip in advance before semiconductor packaging. Substrate warpage is still an issue during manufacturing a substrate strip.

As shown in FIG. 1, a conventional semiconductor package 100 primarily comprises a die-attaching substrate 110, a chip 120, a die-attaching material 130, a plurality of bonding wires 140, and an encapsulant 150. The substrate 110 includes a substrate core 111 with only one layer of bottom solder mask 112 disposed on the external surface 114 of the substrate core 111 where no solder mask is disposed on the die-attaching surface 113 of the substrate core 111. The die-attaching material 130 is directly attached onto the substrate core 111 to firmly attach the chip 120. A plurality of bonding pads 121 of the chip 120 are electrically connected to the bonding fingers 116 of the substrate 110 by a plurality of bonding wires 140 passing through the wire-bonding slot 115 through the substrate 110. An encapsulant 150 encapsulates the chip 120 and the bonding wires 140. A plurality of external terminals 160 are disposed on the external pads 117 on the external surface 114. Normally the substrate core 111 of the substrate 110 is made of glass fibers mixed with resins to enhance the adhesion of die-attaching material 130 to increase die-attaching strength of the chip 120. However, since only a bottom solder mask 112 is disposed on the external surface 114 of the substrate 110, substrate warpage of the substrate 110 will be worse especially implemented for semiconductor packages causing misalignment during handling and processing leading to poor yields. Therefore, a substrate strip having a plurality of die-attaching substrates 110 can not directly be implemented in semiconductor packaging processes.

### SUMMARY OF THE INVENTION

The main purpose of the present invention is to provide a non-planar substrate strip and semiconductor packaging method utilizing the substrate strip with enhanced die-attaching strength to restrain substrate warpage during manufacturing substrate strips for easy handling and processing and to implement die-attaching substrates in semiconductor packaging processes.

According to the present invention, a non-planar substrate strip has a plurality of substrate units and a frame integrally surrounding the substrate units, comprising a substrate core, an external solder mask, and a patterned thick solder mask. The substrate core has a die-attaching surface and an external surface. The external solder mask is formed on the external surface of the substrate core with a first thickness and a first covering area to cover the substrate units. The patterned thick solder mask is formed on the die-attaching surface of the substrate core with a second thickness and a second covering area to cover only the frame with the die-attaching area located inside the substrate units of the substrate core exposed, moreover, the second covering area is smaller than the first covering area and the second thickness is greater than the first thickness. The semiconductor packaging method with the non-planar substrate strip is also revealed.

### DESCRIPTION OF THE DRAWINGS

FIG. 1 shows a cross-sectional view of a conventional semiconductor package.

FIG. 2 shows a 3D view of a non-planar substrate strip according to the preferred embodiment of the present invention.

FIG. 3 shows a cross-sectional view of the non-planar substrate strip according to the preferred embodiment of the present invention.

FIG. 4A to FIG. 4E show cross-sectional views of the non-planar substrate strip during semiconductor packaging processes according to the preferred embodiment of the present invention.

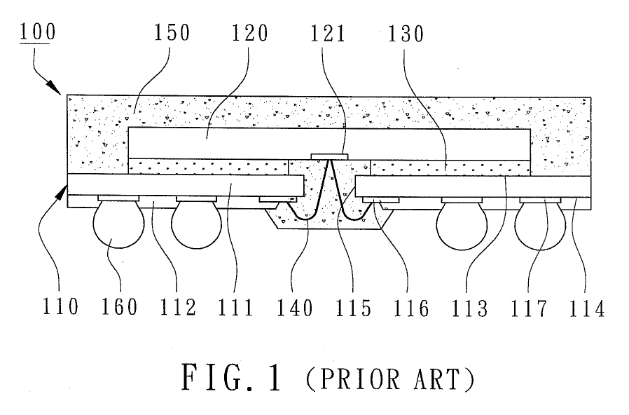

### DETAIL DESCRIPTION OF THE INVENTION

Please refer to the attached drawings, the present invention will be described by means of embodiment below.

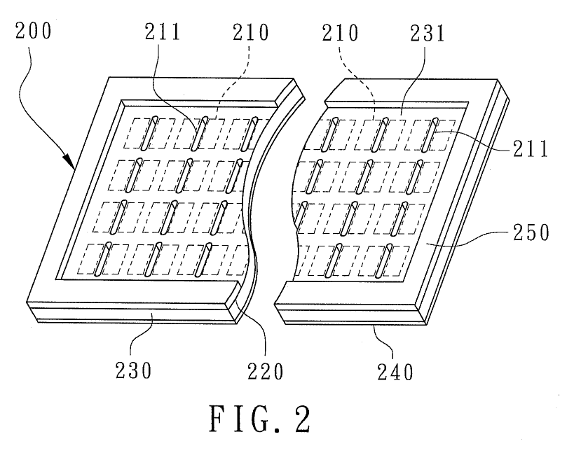

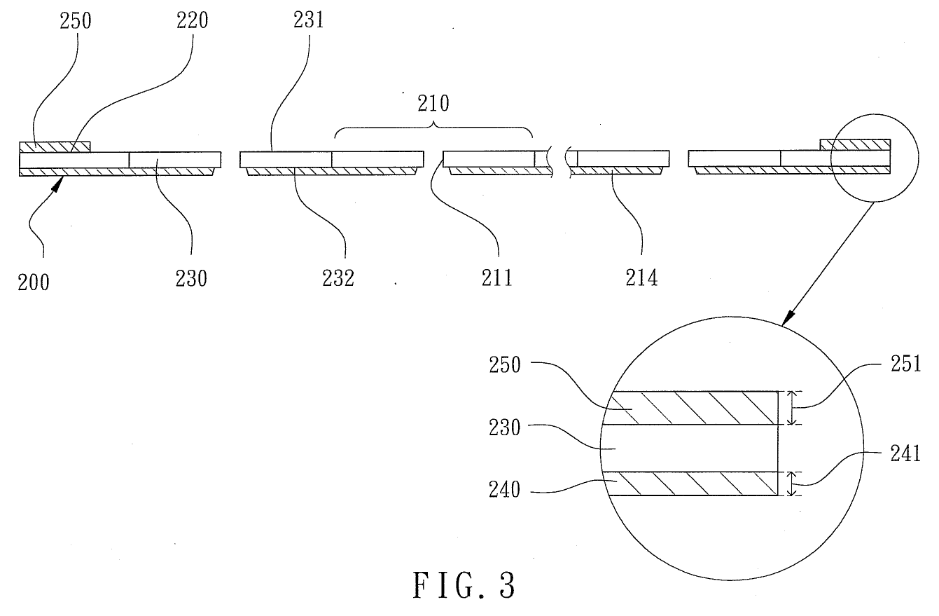

According to this embodiment of the present invention, a non-planar substrate strip 200 for semiconductor packages is revealed. As shown in FIG. 2 and FIG. 3, a non-planar substrate strip 200 has a plurality of substrate units 210 and a frame 220 integrally surrounding the substrate units 210. Each substrate unit 210 is the key component of a semiconductor package to mechanically carry and to electrically connect to a chip, not shown in the figure. The frame 220 does not belong to any parts of the semiconductor package and will be cut off during package sawing. The substrate units 210 are arranged in an array. Each substrate unit 210 has at least a wire-bonding slot 211 for passing bonding wires to electrically connect the chip to the non-planar substrate strip 200.

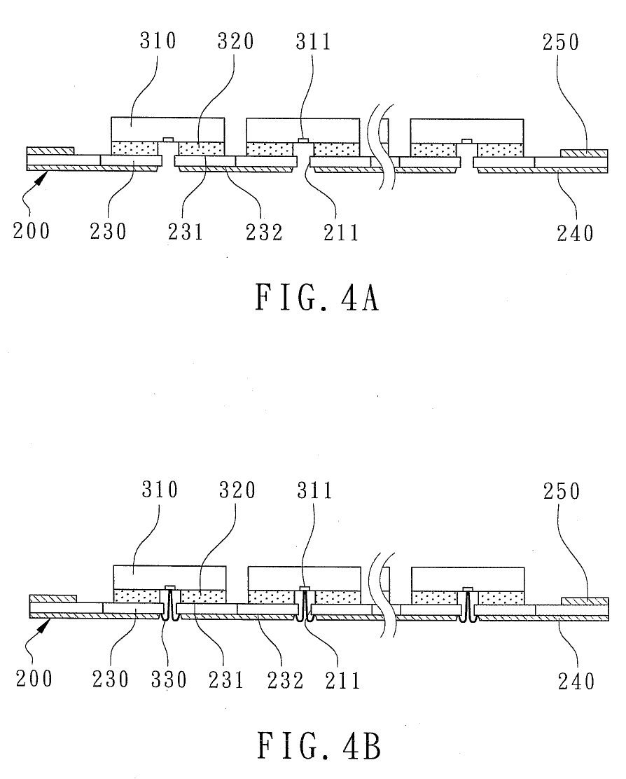

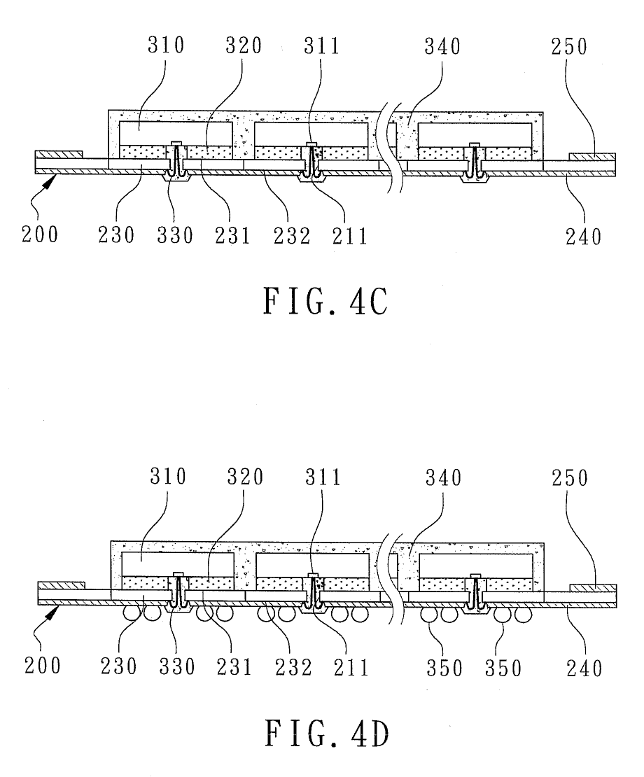

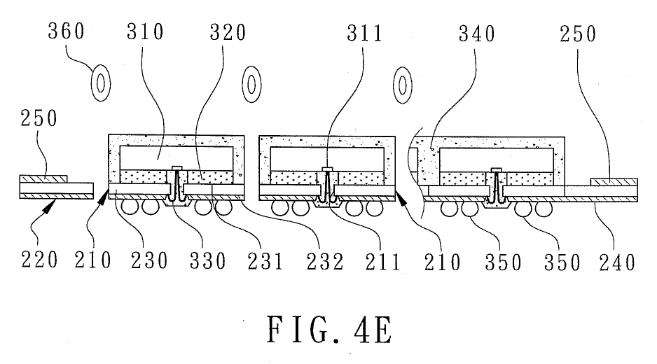

The non-planar substrate strip 200 primarily comprises a substrate core 230, an external solder mask 240, and a patterned thick solder mask 250. As shown in FIG. 3, the substrate core 230 has a die-attaching surface 231 and an external surface 232. The die-attaching surface 231 is used for attaching a plurality of chips, not shown in the figure. A plurality of external pads are disposed on the external surface 232 for bonding a plurality of external terminals 350 as shown in FIG. 4D. The external solder mask 240 is formed on the external surface 232 of the substrate core 230. In this embodiment, the substrate core 230 is made of glass fibers mixed with resins. The patterned thick solder mask 250 and the external solder mask 240 are made of a same insulating material, such as solder mask ink.

As shown in FIG. 2, the patterned solder mask 250 is formed on the die-attaching surface 231 of the substrate core 230 but not covering the substrate units 210 to enhance substrate strengths of the non-planar substrate strip 200 and to avoid substrate warpage. As shown in FIG. 3, the external solder mask 240 has a first covering area and a first thickness 241 to cover the substrate units 210 with the external pads exposed. The patterned thick solder mask 250 has a second covering surface and a second thickness 251 where the second covering area is smaller than the first covering area, as shown in FIGS. 2 and 3. The second covering area only covers the frames 220 with the die-attaching surface 231 of the substrate core 230 located inside the substrate units 210 exposed to enhance the adhesion of the exposed substrate core 230 without increasing the overall thickness of the substrate unit 210. The second thickness 251 is greater than the first thickness 241 to balance the stresses. Therefore, after package sawing, the substrate units 210 become die-attaching substrates. In a more specific embodiment, the second thickness 251 of the patterned thick solder mask 250 ranges from 20 μm to 40 μm and the first thickness 241 of the external solder mask 240 ranges from 10 μm to 30 μm where the thickness difference between the first thickness 251 and the second thickness 241 is about 10 μm. As shown in FIG. 2, in the present embodiment, the frame 220 is rectangular and includes a front side, a rear side, and two side rails, wherein the patterned thick solder mask has a pattern matching to the frame to cover the front side, the rear side, and the side rails. Accordingly, the pattern of the patterned thick solder mask 250 is also a frame.

Therefore, the non-planar substrate strip 200 can enhance the substrate strengths as well as restrain substrate warpage during manufacturing the substrate strip 200 and semiconductor packaging processes since the patterned thick solder mask 250 and the external solder mask 240 are formed in the same printing or dispensing processes with the same solder mask material and are cured at the same time. The substrate strip 200 can be implemented in semiconductor packaging processes with accurate alignment during handling and processing.

As shown from FIG. 4A to FIG. 4E, a semiconductor packaging method with the substrate strip 200 is revealed. Firstly, as shown in FIG. 4A, a plurality of chips 310 are disposed on the die-attaching surface 231 of the substrate core 230 by a die-attaching material 320, i.e., the die-attaching material 320 is directly attached to the substrate core 230 to enhance die-attaching strengths. Each chip 310 has a plurality of bonding pads 311 as external electrodes for the chip 310. In this embodiment, the bonding pads 311 of the chip 310 are faced toward the non-planar substrate strip 200 and are aligned within the corresponding wire-bonding slots 211 of the substrate units 210. As shown in FIG. 4A, the die-attaching surface 231 of the substrate core 230 has a portion located inside the substrate units 210 which has no solder mask formed thereon so that the chips 310 is directly attached to the substrate core 230 by the die-attaching material 320 to enhance the bonding strengths between the chip 310 and the non-planar substrate strip 200. Due to the patterned thick solder mask 250, the non-planar substrate strip 200 has no serious substrate warpage during die-attaching processes.

Then, as shown in FIG. 4B, the chips 310 are electrically connected to the substrate strip 200. In the present embodiment, the bonding pads 311 of each chip 310 is electrically connected to the bonding fingers of the substrate strip 200, not shown in the figure, by a plurality of bonding wires 330 formed by wire-bonding passing through the wire-bonding slot 211. Due to the patterned thick solder mask 250, the non-planar substrate strip 200 has no serious substrate warpage during wire-bonding processes.

As shown in FIG. 4C, an encapsulant 340 is formed on the substrate strip 200 by transfer molding to encapsulate the chips 310 and the bonding wires 330. The encapsulant 340 is directly disposed on the exposed area of the die-attaching surface 231 of the substrate core 230 not covered by the chips 310 on the substrate units 210. In this embodiment, the patterned thick solder mask 250 may be not encapsulated by the encapsulant 340. Due to the patterned thick solder mask 250, the non-planar substrate strip 200 has no serious substrate warpage during molding processes.

Then, as shown in FIG. 4D, the semiconductor packaging method further comprises the step of disposing a plurality of external terminals 350 on the external surface 232 of the non-planar substrate strip 200. In the present embodiment, the external terminals 350 are bonded to the external pads located on the external surface 232 of the substrate strip 200 by solder ball placement or solder paste printing with appropriate reflow conditions. Finally, as shown in FIG. 4E, the encapsulant 340 and the non-planar substrate strip 200 are singulated by a sawing tool 360 to separate the substrate units 210 with the encapsulated chips 310 and to remove the frames 220 with the patterned thick solder mask 250 from the substrate units 210.

Therefore, the non-planar substrate strip 200 can effectively restrain substrate warpage during semiconductor packaging processes to enhance accurate alignment during handling and processing so that the non-planar substrate strip 200 can be implemented in semiconductor packages with a plurality of die-attaching substrates as chip carriers.

The above description of embodiments of this invention is intended to be illustrative and not limiting. Other embodiments of this invention will be obvious to those skilled in the art in view of the above disclosure.

What is claimed is:

1. A non-planar substrate strip for semiconductor packages having a plurality of substrate units and a frame integrally surrounding the substrate units, the strip comprising:
a substrate core having a die-attaching surface and an external surface;
an external solder mask formed on the external surface of the substrate core, wherein the external solder mask has a first covering area and a first thickness, and the first covering area at least covers the substrate units; and
a patterned thick solder mask formed on the die-attaching surface of the substrate core, wherein the patterned thick solder mask has a second covering area and a second thickness, wherein the second covering area is smaller than the first covering area and only covers the frame with the die-attaching surface of the substrate core located inside the substrate unit exposed, wherein the second thickness is greater than the first thickness.

2. The non-planar substrate strip as claimed in claim 1, wherein the second thickness ranges from 20 μm to 40 μm and the first thickness ranges from 10 μm to 30 μm.

3. The non-planar substrate strip as claimed in claim 1, wherein the thickness difference between the second thickness and the first thickness is about 10 μm.

4. The non-planar substrate strip as claimed in claim 1, wherein each substrate unit has at least a wire-bonding slot.

5. The non-planar substrate strip as claimed in claim 1, wherein the frame includes a front side, a rear side, and two side rails, and wherein the patterned thick solder mask has a pattern matching to the frame to cover the front side, the rear side, and the side rails.

6. The non-planar substrate strip as claimed in claim 1, wherein the patterned thick solder mask and the external solder mask are made of a same insulating material.

7. A semiconductor packaging method utilizing the non-planar substrate strip as claimed in claim 1, the method comprising the steps of: disposing a plurality of chips on the die-attaching surface of the substrate core located inside the substrate units by a die-attaching material;
electrically connecting the chips to the non-planar substrate strip;
forming an encapsulant on the exposed area of the die-attaching surface of the substrate core to encapsulate the chips; and
singulating the non-planar substrate strip to separate the substrate units with the encapsulated chip so that the frame with the patterned thick solder mask is removed from the substrate units.

8. The method as claimed in claim 7, wherein the encapsulant is directly attached to the exposed area of the die-attaching surface of the substrate unit without covered by the chips.

9. The method as claimed in claim 7, further comprising the step of disposing a plurality of external terminals on the external surface of the substrate strip.

10. The method as claimed in claim 7, wherein the second thickness ranges from 20 μm to 40 μm and the first thickness ranges from 10 μm to 30 μm.

11. The method as claimed in claim 7, wherein the thickness difference between the second thickness and the first thickness is about 10 μm.

12. The method as claimed in claim 7, wherein each substrate unit has at least a wire-bonding slot for passing through a plurality of bonding wires.

13. The method as claimed in claim 7, wherein the patterned thick solder mask and the external solder mask are made of a same insulating material.
